(19) United States
(12) Patent Application Publication
(10) Pub. No.: US 2013/0118400 A1
(43) Pub. Date: May 16, 2013

(54) METHOD OF FORMING EPITAXIAL ZINC OXIDE FILMS

(71) Applicant: Kia Liang Gregory Goh, Singapore (SG)

(72) Inventor: Kia Liang Gregory Goh, Singapore (SG)

(21) Appl. No.: 13/701,154

(22) PCT Filed: Jun. 3, 2011
(86) PCT No.: PCT/SG11/00203

§ 371 Date: Jan. 25, 2013

(30) Foreign Application Priority Data
Jun. 3, 2010 (US) 61351066

(51) Int. Cl. C30B 19/00; H01L 33/00; C30B 19/12

(52) U.S. Cl. CPC C30B 19/00; C30B 19/12; H01L 33/00
USPC 117/58; 117/54

(57) ABSTRACT

The present invention is directed to a method of forming an epitaxial zinc oxide film on a substrate. The method includes forming an array of nanorods at least substantially perpendicular to the substrate in an aqueous solution; and growing the array of nanorods in an at least substantially lateral direction in the aqueous solution such that adjacent nanorods coalesce to form the epitaxial film. The present invention also relates to the films thus obtained and devices containing said films.

### CROSS-REFERENCE TO RELATED APPLICATION

This application claims the benefit of priority of U.S. provisional application No. 61/351,066, filed 3 Jun. 2010, the content of it being hereby incorporated by reference in its entirety for all purposes.

### TECHNICAL FIELD

Various embodiments relate to a method of forming an epitaxial zinc oxide film on a substrate.

### BACKGROUND

Today, solid-state lighting based on GaN alloys (e.g. gallium-indium-aluminium nitride or GaInAlN) is a multi-billion dollar industry with significant energy savings due to its greater efficiency compared to incandescent lighting sources. This greater efficiency also translates to considerable reductions in electricity required for lighting and so also has beneficial effects on the environment. Recent laboratory demonstrations show that the efficiency of the white-light based GaN light-emitting diodes (LEDs) has even exceeded the efficiency of fluorescent lighting, suggesting even greater energy savings worldwide. In addition, zinc oxide (ZnO) is an ideal emitter for solid-state lighting with more potential than GaN, provided that a consistent p-type ZnO can be developed.

GaN based LEDs are grown on sapphire substrates first and then lifted off from the sapphire substrates in order to package the LED on better heat sink materials such as copper, as the heat generated will affect the stability and efficiency of the LED if the heat is not removed. Growing the GaN LED on a ZnO layer makes the lift off process much easier as the ZnO can be easily etched off with acid while GaN grown directly on sapphire has to be lifted off by a laser process. Therefore, there is a need for epitaxial ZnO layers.

Heteroepitaxy of films leads to line defects, due to lattice mismatch, such as dislocations that are detrimental to device performance. As examples, the lattice mismatch between ZnO and sapphire is very large (e.g. approximately 18.3%) while that between ZnO and silicon is approximately 15.4%, which may lead to dislocations and defects, with adverse effects on the device performance. Those with small lattice mismatch substrates such as GaN-templated sapphire, ZnO substrates and Spinel (MgAl₂O₄) are relatively expensive. Therefore, the ability to grow epitaxial ZnO films on sapphire and silicon substrates may translate to considerable material cost savings.

There are also existing methods to grow films from pre-formed nucleation sites coated on a substrate surface. However, these methods require very high temperature conditions to process the nucleating seed layer.

At present, the bulk of reports on the growth of epitaxial ZnO films have been by vapor phase methods such as Pulse Laser Deposition (PLD), Molecular Beam Epitaxy (MBE), Metal Organic Vapor Chemical Deposition (MOCVD), sputtering and sol-gel method. However, these methods involve complex and long processing methods, rigorous processing conditions and may not be environmentally friendly as some of these processes employ toxic gases. In addition, films grown by the sol-gel method usually have a thickness limitation and require many multiple repeated deposition and heat treatment cycles to grow a film several microns in thickness, which is the required thickness range if such films are to be used as substrates for further device formation.

More recently, there have been reports of the use of solution based methods such as low temperature hydrothermal synthesis and chemical solution deposition. In particular, hydrothermal synthesis and chemical bath deposition tend to form crystalline and epitaxial layers as deposited, while by the sol-gel technique amorphous layers are deposited which are then heat treated to ˜400° C. to obtain an epitaxial layer.

### SUMMARY

In a first aspect of the invention, a method of forming an epitaxial zinc oxide film on a substrate is provided. The method may include forming an array of nanorods at least substantially perpendicular to the substrate in an aqueous solution; and growing the array of nanorods in an at least substantially lateral direction in the aqueous solution such that adjacent nanorods coalesce to form the epitaxial film.

According to another aspect, an epitaxial zinc oxide film is provided. The epitaxial zinc oxide film may be obtained according to the method as described above.

According to a still further aspect, a light emitting diode may be provided. The light emitting diode may include an epitaxial zinc oxide film obtained according to the method as described above.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 shows a flow chart illustrating a method of forming an epitaxial zinc oxide film on a substrate, according to various embodiments.

FIG. 2 shows a schematic diagram illustrating a method of forming an epitaxial zinc oxide film on a substrate, according to various embodiments.

FIG. 3 shows a schematic diagram illustrating a method of forming an epitaxial zinc oxide film on a substrate, according to various embodiments.

FIGS. 4A and 4B show SEM images of a zinc oxide seed layer on a sapphire (0001) substrate, according to various embodiments. The scale bars in FIG. 4A and FIG. 4B represent 100 nm and 1 μm respectively.

FIGS. 5A and 5B show SEM images of zinc oxide nanorods, according to various embodiments. The scale bars in FIGS. 5A and 5B represent 1 μm.

FIGS. 6A and 6B show SEM images of a lateral epitaxial overgrown zinc oxide film, according to various embodiments. The scale bars in FIG. 6A and FIG. 6B represent 100 nm and 1 μm respectively.

FIG. 7A shows an X-ray diffraction (XRD) θ/2θ scan of a ZnO seed layer on a sapphire (0001) substrate, according various embodiments.

FIG. 7B shows an X-ray diffraction (XRD) θ/2θ scan of ZnO nanorods on a sapphire (0001) substrate, according various embodiments.

FIG. 8 shows the pole figures of a (101) plane of a ZnO film and a (012) plane of a sapphire substrate, according to various embodiments.

FIG. 9 shows X-ray diffraction (XRD) 4 scans of a ZnO film grown on an α-Al₂O₃ (0001) substrate, according to various embodiments.

### DETAILED DESCRIPTION

The following detailed description refers to the accompanying drawings that show, by way of illustration, specific details and embodiments in which the invention may be practiced. These embodiments are described in sufficient detail to enable those skilled in the art to practice the invention. Other embodiments may be utilized and structural, logical, and electrical changes may be made without departing from the scope of the invention. The various embodiments are not necessarily mutually exclusive, as some embodiments can be combined with one or more other embodiments to form new embodiments.

Various embodiments provide a method of forming an epitaxial zinc oxide (ZnO) film on a substrate, wherein the method reduces or avoids at least some of the disadvantages connected to conventional methods. In various embodiments, the method may include a hydrothermal process and may be a low temperature solution process. In various embodiments, the substrate may be a lattice mismatch substrate.

The use of solution based methods such as low temperature hydrothermal synthesis processes in various embodiments provide process simplicity and lower costs associated with such a process.

Various embodiments provide a hydrothermal synthesis method of forming an array of ZnO nanorods (e.g. c-axis ZnO nanorods) on large lattice mismatch substrates (e.g., sapphire or silicon substrates) and growing an epitaxial ZnO film from the nanorods. In various embodiments, the solution-based grown nanorods may be of high crystallinity with low occurrence of line defects. In addition, the large lattice mismatch with the substrates makes growing nanorods easier than growing epitaxial films directly on the substrates. In various embodiments, the hydrothermal synthesis method may be carried out at low temperatures.

Various embodiments may provide a method of forming one or more epitaxial ZnO film on lattice mismatch substrates. Therefore, cheaper starting source of materials compared to expensive substrates of closely-matched lattice parameters, may be used. As examples and not limitations, lattice mismatch substrates such as sapphire or silicon may be used for the formation of epitaxial ZnO films. In addition, various embodiments enable reduced defect density of the formed films compared to hetero-epitaxial film growth, simplicity in set up, low temperature growth conditions, lower operating cost, the use of non-toxic chemicals (compared to other processes such as MOCVD) and an environmentally friendly process.

Various embodiments may include the method or technique of lateral epitaxial overgrowth (LEO) to reduce the density of defects, such as line dislocations or threading dislocations, that may be formed due to the lattice mismatch between the epitaxial film and the substrate. In the lateral epitaxial overgrowth (LEO) method, for example of an array of structures formed on a substrate, growth or preferential growth of the structures occurs in an at least substantially lateral direction, where such lateral overgrowths of the structures are at least substantially free of defects such as dislocations. As the lateral overgrowths of the respective structures continue, the lateral overgrowths of adjacent structures coalesce to form an at least substantially continuous film, which is at least substantially free of defects such as dislocations. Nevertheless, at the boundaries between the lateral overgrowths of adjacent boundaries, there may be minimal dislocations. In various embodiments, the LEO process may be used to grow epitaxial films (e.g. epitaxial ZnO films) from nanorods (e.g. ZnO nanorods) grown at least substantially normal or perpendicular to the surface of the substrate.

Conventional epitaxial growth processes produce films with numerous dislocations, which are detrimental to device properties. By using LEO in various embodiments to form or grow epitaxial ZnO films laterally with respect to the substrate as well as normal to the substrate, the dislocation density may be reduced in the formed epitaxial films. In the LEO process, dislocations generated at the interface between the substrate and the films which are growing normally to the substrate may not bend laterally into these overgrown areas, such that these laterally overgrown areas are at least substantially free of dislocations.

Various embodiments may provide a method whereby the epitaxial film formed by the LEO process originates from highly crystalline and low defect (i.e. at least substantially free of defects such as dislocations) single crystal nanorods instead of highly defective epitaxial films, thereby reducing the dislocation density.

Various embodiments may include an approach or a process for decreasing the nanorod density and thus increasing the spacing between the nanorods formed on a substrate, thereby reducing the strain that may be generated in the overgrown film and also reducing the overall dislocation density further.

Various embodiments may provide a method of forming, growing or depositing an epitaxial zinc oxide (ZnO) film or epitaxial zinc oxide (ZnO) films on a substrate or a lattice mismatch substrate. The method may be based on a low temperature solution process.

In various embodiments, the substrates may include but is not limited to spinel (e.g. MgAl₂O₄), gallium nitride (GaN)-templated sapphire, bulk ZnO substrates, sapphire (Al₂O₃) and silicon substrates. The spinel and sapphire substrates may be single crystal substrates. However, it should be appreciated that other substrates may also be used.

In various embodiments, the lattice mismatch substrate for the growth of an epitaxial ZnO film may be a large lattice mismatch substrate, for example where the lattice mismatch between the epitaxial film and the substrate is approximately 5% or more. Sapphire and silicon substrates are lattice mismatch substrates with respect to the epitaxial ZnO film, and provide cheaper alternatives to the other substrates. The lattice mismatch between ZnO and sapphire is very large, for example approximately 18.3%, while that between ZnO and silicon is approximately 15.4%.

In various embodiments, the low temperature solution process may be carried out in an aqueous solution or an aqueous environment. In various embodiments, the aqueous solution or the aqueous environment may be alkaline (basic), with a pH level of more than 7 (i.e. pH>7).

In various embodiments, the method of forming an epitaxial zinc oxide (ZnO) film on a substrate includes nucleating ZnO nanorods, and overgrowing of the ZnO nanorods to form the epitaxial ZnO film. The overgrowth of the ZnO nanorods is in an at least substantially lateral direction from the nanorods.

Due to the large lattice mismatch between ZnO and sapphire substrates (e.g. c-plane sapphire) or silicon substrates (e.g. (111) oriented silicon), it may be easier to nucleate and grow epitaxial ZnO nanorods on these substrates, as compared to, for example, directly growing ZnO film on these substrates.

In various embodiments, the method of forming the epitaxial ZnO film or a part of the method may be performed in a substantially aqueous solution environment, for example using a hydrothermal method. The method may be carried out at low temperatures, for example not exceeding 100° C.

In various embodiments, the epitaxial ZnO film that is formed or grown from the lateral overgrowth of the ZnO nanorods is an at least substantially continuous film.

In various embodiments, the method may further include forming or depositing a ZnO seed layer with nucleating sites for forming the ZnO nanorods. In various embodiments, the seed layer is formed on the substrate in a substantially aqueous solution environment. As an example and not limitation, a ZnO seed layer may be formed on a sapphire substrate to encourage the growth of ZnO nanorods on the sapphire substrate.

In various embodiments, the method may further include an in-situ masking of the substrate such that a masking process may be provided to cover at least substantially parts of the substrate without ZnO nanorods (e.g. exposed parts of the substrate) after forming the ZnO nanorods. This may minimise or prevent the formation of ZnO nanorods on these parts of the substrate during subsequent processing. As an example and not limitation, where ZnO nanorods are formed on a silicon substrate (e.g. silicon (111) substrate), after the epitaxial ZnO nanorods are grown, an oxidation step, which for example may include a heat treatment process, may be carried out to oxidize the exposed parts of the silicon substrate to silicon oxide (SiO₂) so as to form SiO₂ on parts of the silicon substrate that are not covered with nanorods. The SiO₂ areas may prevent ZnO from nucleating normal to the substrate during subsequent processing or overgrowth (LEO).

In various embodiments, in addition or alternative to the in-situ masking process, subsequent processing such as the LEO may be carried out at supersaturations that are sufficiently high for the continued growth of the ZnO nanorods laterally, or laterally and vertically, but sufficiently low to prevent or minimise new ZnO nucleation.

In various embodiments, a lithography process may be carried out to pattern or define areas for the nucleation sites for the selective growth of nanorods on the substrate. The lithography process may also be applied so as to define the spacing between adjacent nanorods, for example to increase the distance or spacing between adjacent nanorods, thereby decreasing the density of the nanorods on the substrate, which facilitates a reduction in the defects (e.g. dislocations) that may be formed.

In various embodiments, the epitaxial ZnO film or films formed may be used as templates for the growth of GaN as the ZnO film may be removed by wet etching, thereby making lift-off of the GaN structure easier for subsequent device packaging, such as LED device packaging.

In the context of various embodiments, the term “lattice mismatch substrate”, with respect to an epitaxial film formed, grown or deposited on a substrate, may mean a substrate having a substrate material with a lattice structure or lattice constant that is different from the lattice structure or the lattice constant of the material of the epitaxial film. In other words, the epitaxial film and the substrate are made of different materials, each having a lattice structure or lattice constant that is different from the other (i.e. lattice mismatch).

In various embodiments, nanorods are formed or grown at least substantially perpendicular (or normal) to the substrate or a surface of the substrate. Subsequently, the array of nanorods is grown in an at least substantially lateral direction such that adjacent nanorods coalesce to form an epitaxial film. In the context of various embodiments, the “lateral direction” may mean a direction that is at least substantially parallel to the surface of the substrate or at least substantially perpendicular to the longitudinal axis of the nanorods. In the context of various embodiments, the term “coalesce” as applied to adjacent nanorods, may mean that the adjacent nanorods adjoin, fuse or come together so as to form a whole structure, which may be a film or continuous film, in various embodiments.

In the context of various embodiments, growing the array of nanorods in an at least substantially lateral direction may include growing the array of nanorods in a vertical direction along a longitudinal axis of the nanorods or in any other directions. In other words, the method of various embodiments, while enabling the growth of the nanorods in the lateral direction or preferentially in the lateral direction, the method does not necessarily exclude the growth of the nanorods in the vertical direction or any other directions.

In the context of various embodiments, the seed layer may be of a material that is at least substantially similar to a material of the nanorods. The seed layer may provide nucleating sites that facilitate the growth of the nanorods. In various embodiments, the seed layer, when formed on a substrate, may facilitate preferential growth of structures, such as nanorods, in a direction at least substantially normal to the substrate.

In the context of various embodiments, the nanorods formed or grown may be single crystal. In addition, the nanorods formed or grown may be c-axis oriented (in other words, the nanorods are grown in a direction normal or perpendicular to the substrate).

In the context of various embodiments, the term “nanorod” may mean a nanostructure extending, for example in a longitudinal direction, with dimensions in the order of nanometers. The term “nanorod” may be used to refer to a nanostructure of any nanometer dimensions (e.g. length, width, diameter or cross-section) and therefore may be used with the same meaning as the terms “nanowire”, “nanopillar”, “nanocolumn” and the likes. In further embodiments, the term “nanorod” may include a microstructure extending, for example in a longitudinal direction, with dimensions in the order of micrometers (microns).

In order that the invention may be readily understood and put into practical effect, particular embodiments will now be described by way of examples and not limitations, and with reference to the figures.

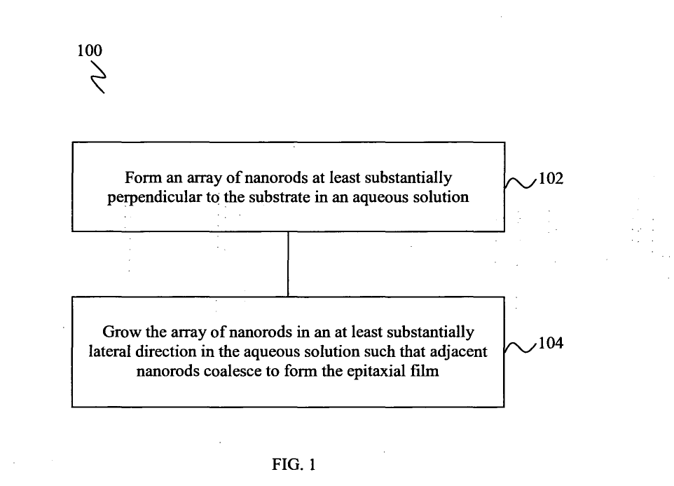

FIG. 1 shows a flow chart 100 illustrating a method of forming an epitaxial zinc oxide (ZnO) film on a substrate, according to various embodiments.

At 102, an array of nanorods is formed at least substantially perpendicular to the substrate in an aqueous solution.

At 104, the array of nanorods is grown in an at least substantially lateral direction in the aqueous solution such that adjacent nanorods coalesce to form the epitaxial film.

In various embodiments, a seed layer may be formed on the substrate in the aqueous solution prior to forming the array of nanorods. In various embodiments, the substrate may be a sapphire substrate or a silicon substrate.

In various embodiments, at least parts of the substrate without nanorods may be masked after forming the array of nanorods. This may include oxidizing the parts of the substrate without nanorods, for example by heating the substrate. In various embodiments, the substrate may be a silicon substrate.

In the context of various embodiments, a patterning process may be performed on the substrate for forming the array of nanorods selectively on the substrate. The patterning process may be performed on the substrate prior to forming the array of nanorods. In various embodiments, the patterning process may include a lithography process, for example photolithography or electron beam (e-beam) lithography.

In the context of various embodiments, the aqueous solution may be an alkaline aqueous solution. The alkaline aqueous solution may have a pH level of between about 7 to about 12, for example between about 8 to about 10.

In the context of various embodiments, the aqueous solution may be at a temperature of between about 40° C. to about 250° C., for example between about 90° C. to about 200° C. or between about 120° C. to about 150° C. In other words, the process or processes carried out in the aqueous solution or alkaline aqueous solution may be carried out at a temperature of between about 40° C. to about 250° C.

In the context of various embodiments, a spacing between adjacent nanorods of the array of nanorods may be between about 100 nm to about 50 μm (50 000 nm), for example between about 500 nm to about 40 μm, between about 1 μm to about 30 μm or between about 10 μm to about 20 μm.

In the context of various embodiments, the epitaxial film may be at least substantially continuous.

In the context of various embodiments, processing in the aqueous solution or alkaline aqueous solution may or may not be continuous. For example, after forming the nanorods on the substrate, the substrate with the nanorods may be removed for further processing, for example for masking of the exposed parts of the substrate, before further processing in the alkaline aqueous solution, for example for lateral epitaxial overgrowth to form an epitaxial film.

In the context of various embodiments, the substrate may include a substrate material having a lattice structure different from that of the epitaxial film.

In the context of various embodiments, an epitaxial zinc oxide film may be obtained according to the method as described above.

In the context of various embodiments, a light emitting diode (LED) including an epitaxial zinc oxide film may be provided. The epitaxial zinc oxide film may be obtained according to the method as described above.

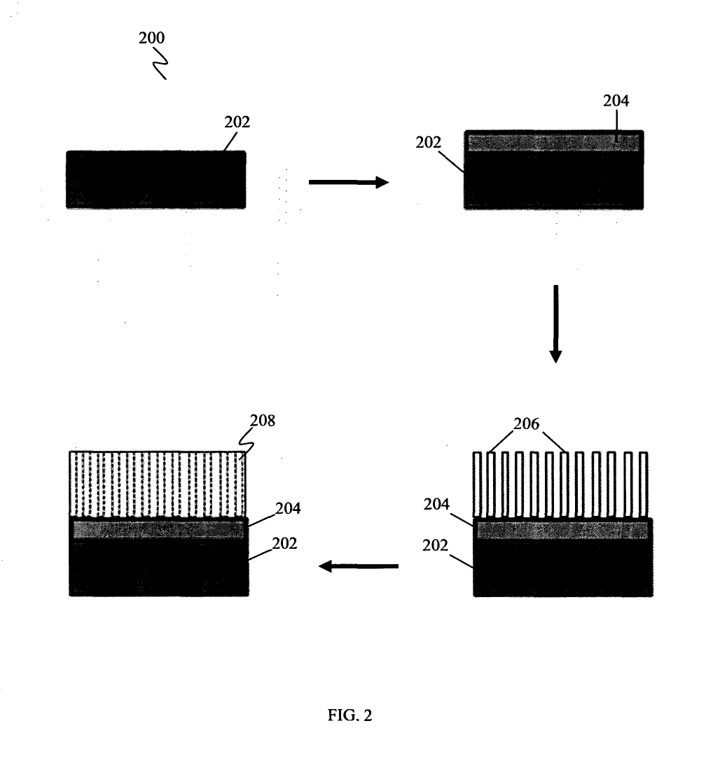

FIG. 2 shows a schematic diagram 200 illustrating a method of forming an epitaxial zinc oxide (ZnO) film on a substrate, according to various embodiments. As an example and not limitation, the schematic diagram 200 illustrates a method of forming or growing an epitaxial ZnO film on a sapphire substrate (e.g. sapphire (0001) substrate).

In various embodiments of a method of forming an epitaxial ZnO film or films on a sapphire substrate, the method may include forming one or more seed layers (e.g. ZnO seed layer), forming or growing epitaxial and upright ZnO nanorods, and applying a lateral epitaxial overgrowth (LEO) approach to form the epitaxial ZnO film. In various embodiments, the seed layer includes one or more nucleation or nucleating sites for facilitating or encouraging the growth of the nanorods.

Referring to FIG. 2, a substrate (e.g. sapphire (0001) substrate) 202 is provided. The sapphire substrate 202 is cleaned with acetone and isopropyl alcohol (IPA). The sapphire substrate 202 may then be transferred into a Teflon vessel containing an aqueous solution, for example the sapphire substrate 202 is placed faced down on a Teflon holder into the aqueous solution, in order to grow one or more ZnO seed layers on the sapphire substrate 202.

In various embodiments, the aqueous solution in the Teflon vessel contains approximately 145 mg of zinc nitrate (Zn(NO₃)₂.2H₂O) (from Sigma-Aldrich) and approximately 600 mg of ammonium nitrate (NH₄NO₃) (from Fluka) in approximately 24 ml of de-ionised (DI) water that is pre-heated at about 90° C. for about 1.5 hours. Approximately 1 ml of dilute 25% ammonium hydroxide (NH₃ or NH₄OH) in a ratio of 1:10 with DI water is added immediately to the aqueous solution after the substrate transfer, in order to increase the pH level of the aqueous solution and to initiate the precipitation of ZnO. The amount of ammonium hydroxide added is calibrated by raising the pH level of a room temperature solution to approximately 7.6. The substrate 202 is maintained in the solution for about 6 hours at about 90° C., for example by placing the vessel in an oven, to form one or more ZnO seed layers on the sapphire substrate 202 to create nucleation sites for the subsequent growth of nanorods. As shown in FIG. 2, a ZnO seed layer 204 is formed on the sapphire substrate 202.

In various embodiments, an aqueous solution of approximately 180 mg of zinc nitrate (Zn(NO₃)₂₋₂H₂O) (from Sigma-Aldrich) in approximately 24 ml of DI water at room temperature is prepared in a Teflon vessel. Approximately 1.4 ml of 25% ammonium hydroxide is added immediately to the aqueous solution in order to increase the pH level of the aqueous solution to approximately 10.9. The sapphire substrate 202 with the ZnO seed layer 204 formed thereon is then introduced into the solution. Subsequently, the vessel is placed in an oven at about 90° C. for about 1 hour in order to grow c-axis oriented ZnO nanorods from the nucleation sites of the ZnO seed layer 204. As shown in FIG. 2, an array of ZnO nanorods, as represented by 206 for two ZnO nanorods, are formed or grown.

In various embodiments, subsequently, the sapphire substrate 202 with the grown ZnO nanorods 206 is placed in a Teflon vessel containing an aqueous solution of approximately 180 mg of zinc nitrate (Zn(NO₃)₂.2H₂O) (from Sigma-Aldrich) and approximately 50 mg of sodium citrate (from Sigma) in approximately 24 ml of DI water at room temperature. Approximately 1.0 ml of 25% ammonium hydroxide is added to the aqueous solution in order to increase the pH level of the aqueous solution to approximately 10.9. Subsequently, the vessel is placed into a stainless steel bomb, which is then placed in an oven at about 90° C. for about 24 hours to enable lateral epitaxial overgrowth (LEO) of the ZnO nanorods 206 to form an epitaxial ZnO film. As shown in FIG. 2, an epitaxial ZnO film 208 is formed.

In various embodiments, a patterning process such as a lithography process may be carried out on the substrate to pattern or define areas of the substrate for the selective growth of nanorods on the substrate.

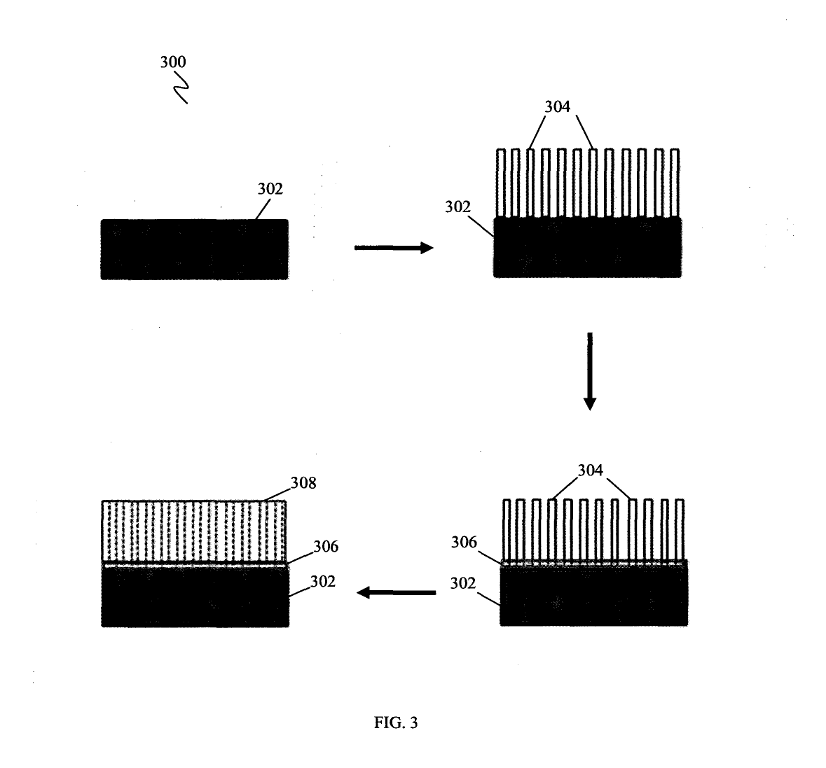

FIG. 3 shows a schematic diagram 300 illustrating a method of forming an epitaxial zinc oxide (ZnO) film on a substrate, according to various embodiments. As an example and not limitation, the schematic diagram 300 illustrates a method of forming or growing an epitaxial ZnO film on a silicon (Si) substrate (e.g. silicon (111) substrate).

In various embodiments of a method of forming an epitaxial ZnO film or films on a silicon substrate, the method may include nucleating, forming or growing epitaxial and upright ZnO nanorods, oxidising parts of the exposed silicon substrate where there are no nanorods, and applying a lateral epitaxial overgrowth (LEO) approach to form the epitaxial ZnO film.

Referring to FIG. 3, a substrate (e.g. silicon (111) substrate) 302 is provided. The silicon substrate 302 is cleaned with acetone and isopropyl alcohol (IPA). The silicon substrate 302 is then placed in a Teflon vessel containing an aqueous solution of ZnO precursor for forming ZnO nanorods. The processing parameters, conditions and sequence may be substantially similar to that as described above with respect to forming ZnO nanorods on the sapphire substrate. Therefore, the process of forming ZnO nanorods in the context of the sapphire substrate may correspondingly be applicable to the silicon substrate. As shown in FIG. 3, an array of ZnO nanorods, as represented by 304 for two ZnO nanorods, are formed or grown on the silicon substrate 302.

In various embodiments, oxidation of the exposed parts of the silicon substrate, where there are no ZnO nanorods, to silicon oxide (SiO₂) may be carried out, for example by carrying out a heat treatment process on the silicon substrate. In various embodiments, the oxidation process may be performed by carrying out a heat treatment process on the silicon substrate at about 500° C. As shown in FIG. 3, a layer of SiO₂ 306 may be formed.

In various embodiments, the silicon substrate 302, with the grown ZnO nanorods 304 and the layer of SiO₂ 306, is then placed in a Teflon vessel containing an aqueous solution for the lateral epitaxial overgrowth (LEO) of the ZnO nanorods 304 to form an epitaxial ZnO film. The processing parameters, conditions and sequence may be substantially similar to that as described above with respect to the lateral epitaxial overgrowth of the ZnO nanorods on the sapphire substrate. Therefore, the process of lateral epitaxial overgrowth of the ZnO nanorods in the context of the sapphire substrate may correspondingly be applicable to the silicon substrate. As shown in FIG. 3, an epitaxial ZnO film 308 is formed.

In various embodiments, one or more ZnO seed layers may be formed or deposited on the silicon substrate 302 in a substantially similar approach to that as described above with respect to forming one or more ZnO seed layers on a sapphire substrate. Therefore, the process of forming one or more ZnO seed layers in the context of a sapphire substrate may applicable be to a silicon substrate.

In various embodiments, a patterning process such as a lithography process may be carried out on the substrate to pattern or define areas of the substrate for the selective growth of nanorods on the substrate.

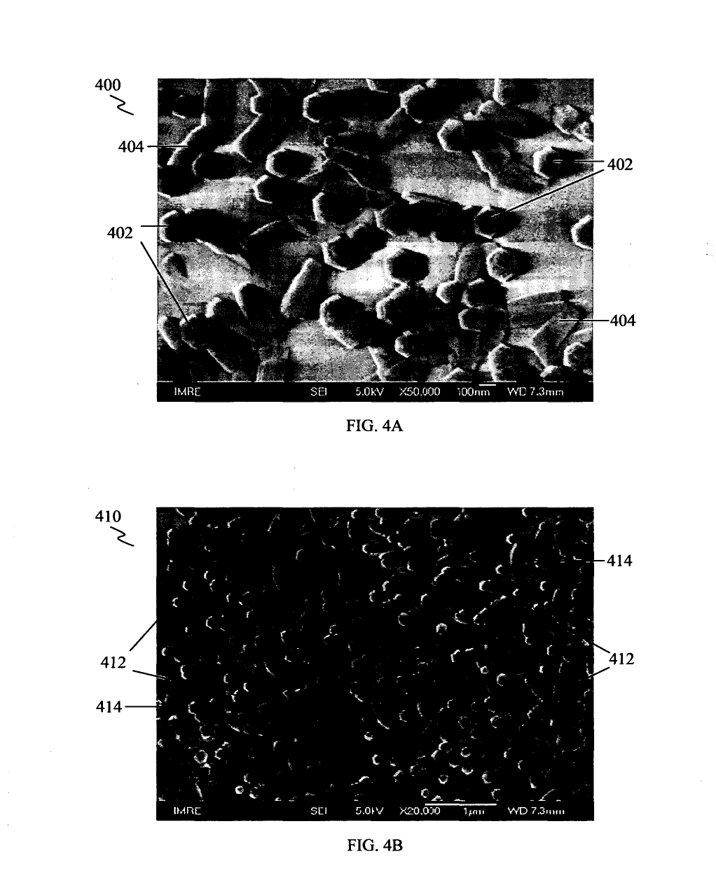

FIGS. 4A and 4B show SEM images 400 and 410 respectively of a top view of a zinc oxide (ZnO) seed layer on a sapphire (0001) substrate, according to various embodiments. As can be seen in the SEM image 400, there are a plurality of nanostructures or nanoparticles. These plurality of nanostructures are ZnO nanostructures, as can be seen from the hexagonal shapes of the nanostructures as ZnO has a wurtzite structure, which is part of a hexagonal crystal system. Some of these nanostructures, for example as represented by 402 for four such nanostructures, grow upright or normal to the substrate (i.e. in a direction pointing out of the page), while some other nanostructures, for example as represented by 404 for two such nanostructures, lie on their sides. In various embodiments, these plurality of nanostructures 402, 404, serve as nucleation sites for the growth of nanorods in subsequent processing. Similar for FIG. 4B, the SEM image 410 show a plurality of nanostructures 412 which grow upright or normal to the substrate and nanostructures 414 which lie on their sides.

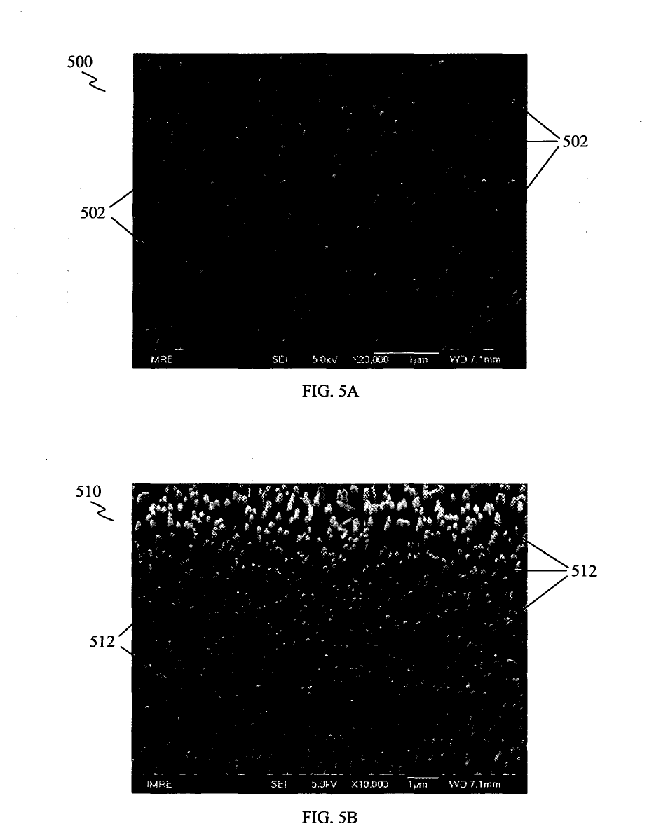

FIG. 5A shows an SEM image 500 of an array of zinc oxide (ZnO) nanorods, as represented by 502 for five such nanorods, and FIG. 5B shows an SEM image 510 of an array of zinc oxide (ZnO) nanorods, as represented by 512 for five such nanorods, according to various embodiments. The nanorods 502, 512, are obtained after one hour of growth of nanorods based on the nucleation sites on the seed layer (e.g. as shown in the SEM images 400 and 410 of FIGS. 4A and 4B respectively). As can be seen in FIGS. 5A and 5B, the nanorods 502, 512, grow upright or normal to the substrate.

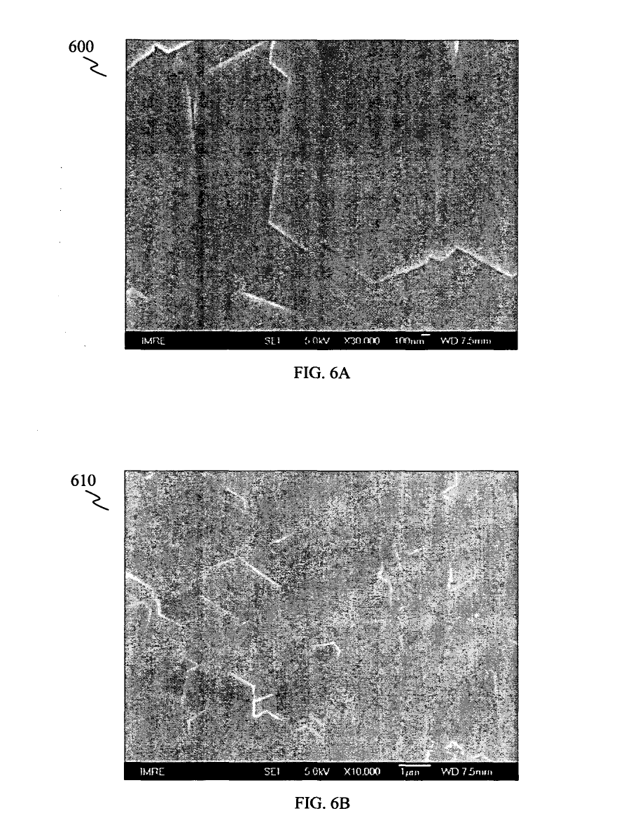

FIGS. 6A and 6B show SEM images 600 and 610 respectively of a lateral epitaxial overgrown zinc oxide (ZnO) film, according to various embodiments. As can be seen in FIGS. 6A and 6B, the respective lateral epitaxial overgrown ZnO film is continuous.

The crystallinity and orientation, including the crystal structure of the seed layer, nanorods and epitaxial ZnO films of various embodiments may be analysed using X-ray diffraction (XRD), for example using the PANalytical X′Pert PRO High Resolution XRD.

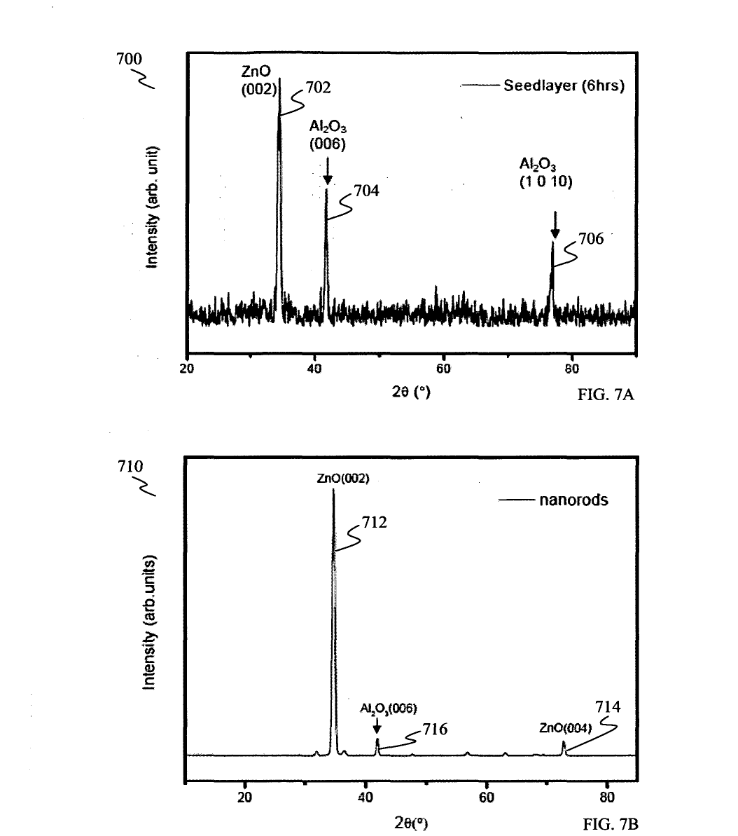

FIG. 7A shows an X-ray diffraction (XRD) θ/2θ scan 700 of a ZnO seed layer on a sapphire (0001) substrate, according various embodiments. The ZnO seed layer is formed after 6 hours of processing or deposition. As can be observed in FIG. 7A, the seed layer is c-axis oriented, as observed from the strong peak 702 attributed to the (002) crystal plane of ZnO. In addition, the observed peaks 704 and 706 attributed to different crystal planes of Al₂O₃ are due to the sapphire (0001) substrate.

FIG. 7B shows an X-ray diffraction (XRD) θ/2θ scan 710 of ZnO nanorods on a sapphire (0001) substrate, according various embodiments. As can be observed in FIG. 7B, the ZnO nanorods have c-axis orientations, as observed from the strong peak 712 attributed to the (002) crystal plane of ZnO. In addition, a peak 714 attributed to the (004) crystal plane of ZnO may be observed. The contrast in the strength or height of the peaks 712 and 714 show that the ZnO nanorods preferentially grow in the c-axis direction (i.e. in a direction normal or perpendicular to the sapphire (0001) substrate). In addition, a peak 716 may be observed, which is attributed to the (006) crystal plane of Al₂O₃, originating from the sapphire (0001) substrate.

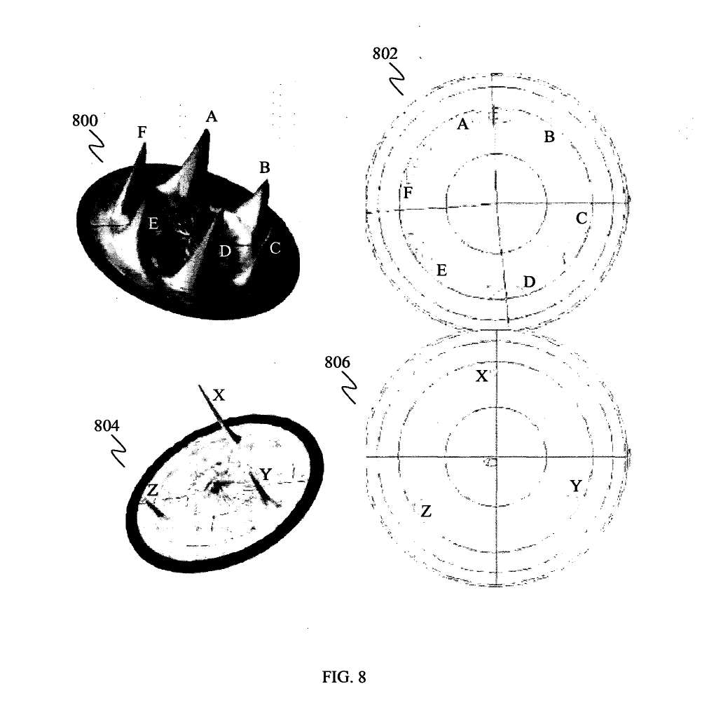

FIG. 8 shows the pole figures 800 and 802 of a (101) plane of a ZnO film and the pole figures 804 and 806 of a (012) plane of a sapphire substrate, according to various embodiments. The pole figures as shown in FIG. 8 illustrate the epitaxial nature of the ZnO film formed.

A pole figure may provide a graphical representation of the orientation of crystallographic lattice planes of a material. The pole figure may be obtained or scanned by measuring the diffraction intensity of a given reflection at a number of angular orientations of a sample. Referring to FIG. 8, the pole figures 800 and 804 show the variation in X-Ray intensity with angular position obtained by the pole figure measurement, while the pole figures 802 and 806 are the plan views of pole figures 800 and 804 respectively. FIG. 8 shows that both ZnO (pole figures 800 and 802) and sapphire (804 and 806) have hexagonal crystal structures. In addition, the pole figures 802 (ZnO) and 806 (sapphire) show that when the ZnO film is formed on the sapphire substrate, the ZnO hexagon is at least substantially aligned with the sapphire hexagon.

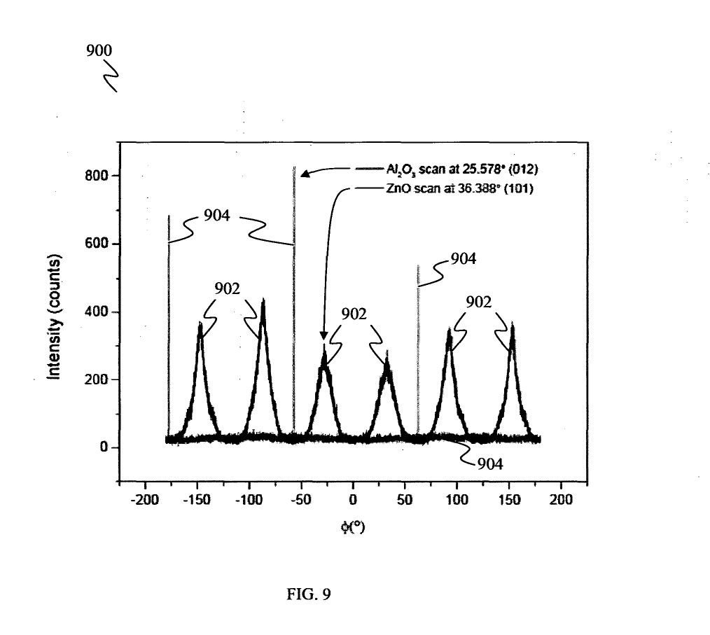

An XRD off-axis Φ-scan may be performed on the ZnO (101) and sapphire (012) planes in order to determine the in-plane orientation of the epitaxial ZnO film, for example by scanning along any circle that passes through the peaks, for example peaks A, B, C, D, E and F (as shown for pole figures 800 and 802 of FIG. 8) for ZnO and peaks X, Y and Z (as shown for pole figures 804 and 806 of FIG. 8) for sapphire. FIG. 9 shows a plot 900 of the X-ray diffraction (XRD) Φ scans 902 and 904 respectively of a ZnO film grown on an α-Al₂O₃ (0001) substrate, and the α-Al₂O₃ (0001) substrate, according to various embodiments. The six Φ-scan peaks 902 at 60° intervals show that the epitaxial ZnO film exhibits a single-domain wurtzite structure with hexagonal symmetry. The respective peaks of the substrate (i.e. 904) and the film (i.e. 902) are separated by approximately 30° in the Φ-axis, indicating an in-plane orientation or an epitaxial relationship of ZnO [10 1̅0]∥Al₂O_{3 [}11 2̅0].

In addition, in various embodiments, the rocking curve or w-scans (not shown) of the (0002) plane for the epitaxial ZnO film yields a full width half maximum (FWHM) of apprpximately 1°.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

1. A method of forming an epitaxial zinc oxide film on a substrate, the method comprising:
forming an array of nanorods at least substantially perpendicular to the substrate in an aqueous solution; and
growing the array of nanorods in an at least substantially lateral direction in the aqueous solution such that adjacent nanorods coalesce to form the epitaxial film.

2. The method of claim 1, wherein the method further comprises forming a seed layer on the substrate in the aqueous solution prior to forming the array of nanorods.

3. The method of claim 1 or 2, wherein the substrate comprises a substrate material having a lattice structure different from that of the epitaxial film.

4. The method of claim 3, wherein the substrate comprises sapphire or silicon.

5. The method of any one of claims 1-3, wherein the method further comprises masking at least parts of the substrate without nanorods after forming the array of nanorods.

6. The method of claim 5, wherein masking at least parts of the substrate without nanorods comprises oxidizing the parts of the substrate without nanorods.

7. The method of claim 6, wherein oxidizing the parts of the substrate without nanorods comprises heating the substrate.

8. The method of any one of claims 5-7, wherein the substrate comprises silicon.

9. The method of any one of claims 1-8, further comprising:
performing a patterning process on the substrate for forming the array of nanorods selectively on the substrate.

10. The method of claim 9, wherein the patterning process comprises a lithography process.

11. The method of any one of claims 1-10, wherein the aqueous solution is an alkaline aqueous solution.

12. The method of claim 11, wherein the alkaline aqueous solution has a pH level of between about 7 to about 12.

13. The method of any one of claims 1 to 12, wherein the aqueous solution is at a temperature of between about 40° C. to about 250° C.

14. The method of any one of claims 1 to 13, wherein a spacing between adjacent nanorods of the array of nanorods is between about 100 nm to about 50 μm.

15. The method of any one of claims 1 to 14, wherein the epitaxial film is at least substantially continuous.

16. Epitaxial zinc oxide film obtained according to the method of any one of claims 1-15.

17. Light emitting diode comprising the epitaxial zinc oxide film according to claim 16.
